(19) United States
(12) Patent Application Publication
(10) Pub. No.: US 2009/0292849 A1
(43) Pub. Date: Nov. 26, 2009

(54) ADAPTABLE PCI EXPRESS CONTROLLER CORE

(76) Inventor: Ken KHOO, Singapore (MY)

Correspondence Address: O2MICRO INC;C/O MURABITO, HAO & BARNES LLP, TWO NORTH MARKET STREET, THIRD FLOOR, SAN JOSE, CA, 95113, US

(21) Appl. No.: 12/125,643

(22) Filed: May 22, 2008

(51) Int. Cl. H05K 7/10

(52) U.S. Cl. 710/301

(57) ABSTRACT

A controller core for controlling communication of Peripheral Component Interconnect (PCI) Express, the controller core comprises: a standard configuration register unit, a capabilities register unit, a logic unit and a bond option signal. The standard configuration register unit is configured for controlling the communication of the PCI-E, and supporting the controller core been embedded internally and accessible from exterior. The logic unit applied to associate with the standard configuration register unit and the capabilities register unit for identifying a hot insertion and removal from exterior of the controller core; and the bond option signal is used to enable and disenable the standard configuration register unit, the capabilities register unit, and the logic unit respectively.

### TECHNICAL FIELD

The invention relates to peripheral component interconnect Express (PCI-E) devices, and more particularly, to an PCI-E controller.

### BACKGROUND ART

In computer systems, a fast and flexible transactions infrastructure is desirable to provide connectivity to devices capable of high levels of data throughput. For example, in the fields of data transfer between devices in a computer system, PCI-E can be used to provide connectivity between a host and one or more client devices or endpoints.

Formerly known as Third-Generation I/O (3GIO), PCI-E is the open standards based successor to PCI and its variants for server and client-system I/O interconnects. Unlike PCI which is based on 32-bit and 64-bit parallel buses, PCI-E uses high-speed point-to-point serial link technology and is compatible with existing PCI cards.

For controlling data transfer between devices via PCI-E bus in a computer system, a PCI-E controller allows physical system decoupling through high-speed serial I/O and is designed for supporting PCI-E base specification, which sets out behavior requirements of devices using the PCI-E interconnect standard. The PCI-E controller can be integrated into the internal computer system for controlling data communication. However, this internal PCI-E controller may not satisfy the requirement of hot swappable PCI-E standard.

On the other hand, the PCI-E controller can be plugged from the exterior of the computer system when the hot-plug control function is supported according to the PCI-E Specification. For instance, the ExpressCard Standard, which is a standard developed by the Personal Computer Memory Card International Association (PCMCIA) in 2005 for supporting hot swappable systems and modules, is designed to deliver expansion by inserting ExpressCard modules into compliant systems. The ExpressCard standard gives users an easy way to add hardware or media to computer systems, and provides desktop and mobile computer users a consistent way to connect devices into their computer systems.

Furthermore, the manufacturing costs will be high when two kinds of PCI-E chips are designed respectively to satisfy the internal and external applications. In prior art, the internal PCI-E controller chip and the external ExpressCard chip are produced individually to meet different requirements respectively. Therefore, it is desirable to provide an adaptable PCI-E controller core which can be used in different applications so as to lower manufacturing costs.

### SUMMARY OF THE INVENTION

It is an object of the present invention to provide an adaptable peripheral component interconnect Express (PCI-E) controller core which can be integrated in the internal system PC platform or plugged from the exterior.

In order to achieve the above object, the present invention provides a controller core for controlling communication of a Peripheral Component Interconnect (PCI) Express interface. In one embodiment, the controller core comprises: a standard configuration register unit, a capabilities register unit, a logic unit and a bond option signal. The standard configuration register unit is configured for controlling the communication of the PCI-E, and supporting the controller core being embedded internally and accessible from the exterior. The logic unit operates cooperatively with the standard configuration register unit and the capabilities register unit for identifying a hot insertion and removal from the exterior of the controller core; and the bond option signal coupled to the standard configuration register unit, the capabilities register unit, and the logic unit for enabling and disenabling the standard configuration register unit, the capabilities register unit, and the logic unit respectively.

### BRIEF DESCRIPTION OF THE DRAWINGS

Features and advantages of embodiments of the claimed subject matter will become apparent as the following Detailed Description proceeds, and upon reference to the Drawings, wherein like numerals depict like parts, and in which:

FIG. 1 is a block diagram showing an adaptable peripheral component interconnect Express (PCI-E) controller in accordance with one embodiment of the present invention.

FIG. 2 is a block diagram showing a host system with the controller core shown in FIG. 1, in accordance with one embodiment of the present invention.

FIG. 3 is a diagram showing a method for manufacturing PCI-E controllers in accordance with one embodiment of the present invention.

### DESCRIPTION OF THE EMBODIMENT

Reference will now be made in detail to the embodiments of the present invention, a battery charge/discharge control circuit. While the invention will be described in conjunction with the embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

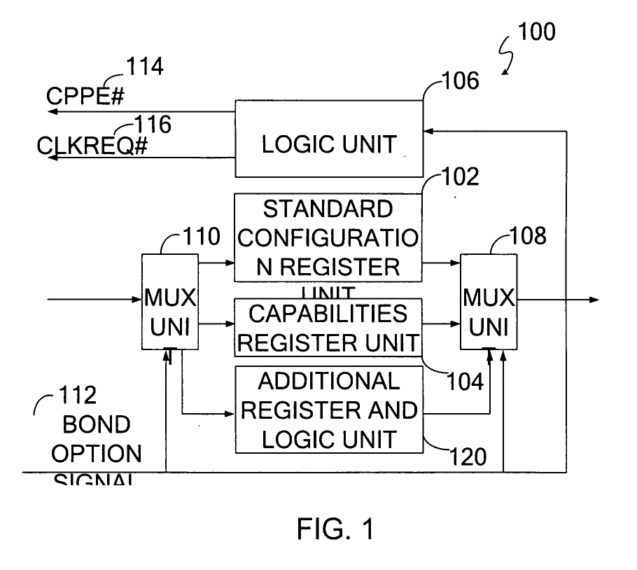

Referring to FIG. 1, a peripheral component interconnect Express (PCI-E) controller core 100 for controlling PCI-E communication according to one embodiment of the present invention is illustrated. The PCI-E controller core 100 is operated with a computer system, not shown. In the FIG. 1 embodiment, the controller core 100 comprises a standard configuration register unit 102, a capabilities register unit 104, a logic unit 106, two selectors, such as MUX units 108 and 110, and an additional register logic and unit 120.

Both MUX units 108 and 110 are coupled to the standard configuration register unit 102 and the capabilities register unit 104. A bond option signal 112 is coupled to the MUX units 108 and 110 for controlling these units, and coupled to the logic unit 106 for enabling it. According to one embodiment of the present invention, the controller core 100 is formed as an integral circuit (IC) die. The bond option signal 112 can be coupled to an I/O pad of the IC die which is used for receiving the external bond option signal so as to enable or disenable the units of the controller core 100. After the bond option signal is received, certain units of the controller core 100 can be enabled or disenabled and the controller core 100 can be packaged into an IC chip which can serve as an internal PCI-E controller or an external PCI-E controller.

The standard configuration register unit 102 comprising the combination of registers and logic which is needed to realize the basic communication defined in the PCI-E base Specification. For example, the standard configuration register unit 102 should comprehend different data types and ordering, have ability to support differentiated services, i.e., different Qualities of Service (QoS) and multi-hierarchy and advanced peer-to-peer communications. The unit 102 also is capable of processing independently, handling error data and keeping data integrity. When the standard configuration register unit 102 is enabled, the controller core 100 can be used to support the basic PCI-E communication.

The capabilities register unit 104 and the logic unit 106 are designed for identifying hot insertion and removal from the exterior of the controller core 100. The hot-plug and hot-swap function is also defined in the PCI-E Specification in detail. The PCI-E Specification defines the standard usage model supporting hot plug and hot removal of devices. The standard usage model provides the foundation for how indicators and push buttons for all PCI-E hot-plug models should behave. The capabilities register unit 104 and the logic unit 106 comply with the PCI-E Specification. As such, the capabilities register unit 104 and logic unit 106 support existing PCI-E hot-plug and hot-swap solutions, native hot-plug and hot-swap solutions and a unified software model.

The capabilities register unit 104 comprises a plurality of slot capabilities registers (not shown) for identifying hot insertion and removal of the controller core 100 from the exterior of the host computer system. The operations of the capabilities register unit 104 will be described in detail hereinafter.

The logic unit 106 comprises a PCI-E interface detect logic signal 114 and a clock request logic signal 116. This PCI-E interface detect logic signal 114, such as a signal CPPE# defined in ExpressCard Standard, is designed for detecting PCI-E based devices. The signal is used to indicate controller presence for PCI-E based modules. The primary purpose of the controller detect logic signal 114 is to inform the internal host system of the computer system that a module/controller is present in the slot and then the power of the slot will be turned on by the computer system. The clock request logic signal 116 is designed for providing a reference clock signal to PCI-E based devices which may be inserted into a slot of the host computer system. PCI-E based modules, such as the clock request logic signal 116, which is defined in ExpressCard Standard as CLKREQ#, is an open drain, active low signal that is asserted to the host platform when the module needs to have reference clock enabled for the PCI-E interface to operate.

The bond option signal 112 is a control signal from the exterior of the controller core 100 for controlling the MUX units 108 and 110, in order to meet different requirements of integrating the PCI-E controller core 100 internally or packaging it as a hot-swappable external device of the host computer system, in accordance with embodiments of the present invention. The standard configuration register unit 102 and the capabilities register unit 104 are enabled or disenabled through the MUX units 108 and 110 in response to the bond option signal 112. The bond option signal 112 is also used to control the logic unit 106.

In one embodiment, when the bond option signal 112 enables the standard configuration register unit 102 and disenables the capabilities register unit 104 through the MUX units 108 and 110 and also disables the logic unit 106, the controller core 100 can be installed in the host computer system as an internal component. Those skilled in the art will recognize that the controller core 100 can be formed or manufactured as a die which will subsequently be packaged into a chip. When the bond option signal 112 is used in the aforementioned manner, the chip will be recognized as an internal device by Operating System (OS) and Basic Input/Output System (BIOS) of the host computer system.

In another embodiment, when the bond option signal 112 enables the standard configuration register unit 102 and the capabilities register unit 104 through MUX unit 108 and MUX unit 110, and also enables the logic unit 116, the controller core 100 supports hot-swap from the exterior of the host computer system. Similarly, after the tape-out step which is the final stage of the design cycle of integrated circuits or printed circuit boards, at which the description of the circuit of the controller core 100 is sent for manufacture, the controller core 100 can be packaged to be another type of chip, which will be recognized as an external module of the host computer system.

As stated hereinbefore, the adaptable controller core 100 can be packaged into two kinds of chips in response to the bond option signal in accordance with embodiments of the present invention. Therefore, low costs and high efficiency of manufacturing is achieved.

Furthermore, in order to support other communication bus interfaces such as Media Card interface, Electrical and Electronics Engineers (IEEE) 1394 interface, and CardBus interface, the PCI-E controller core 100 comprises an additional register and logic unit 120 coupled to the MUX units 108 and 110 for supporting the external device communication bus interfaces. The additional register and logic unit 120 is controlled by the bond option signal 112 through the MUX units 108 and 110. When an external device such as the Media Card is to be inserted into a slot, not shown, of the controller core 100, the additional register and logic unit 120 is enabled by the bond option signal 112. As such, the Media Card can communicate with the host computer system by using the controller core 100 after it has been packaged into an internal/external controller and integrated a corresponding Media Card slot where the Media Card can be inserted.

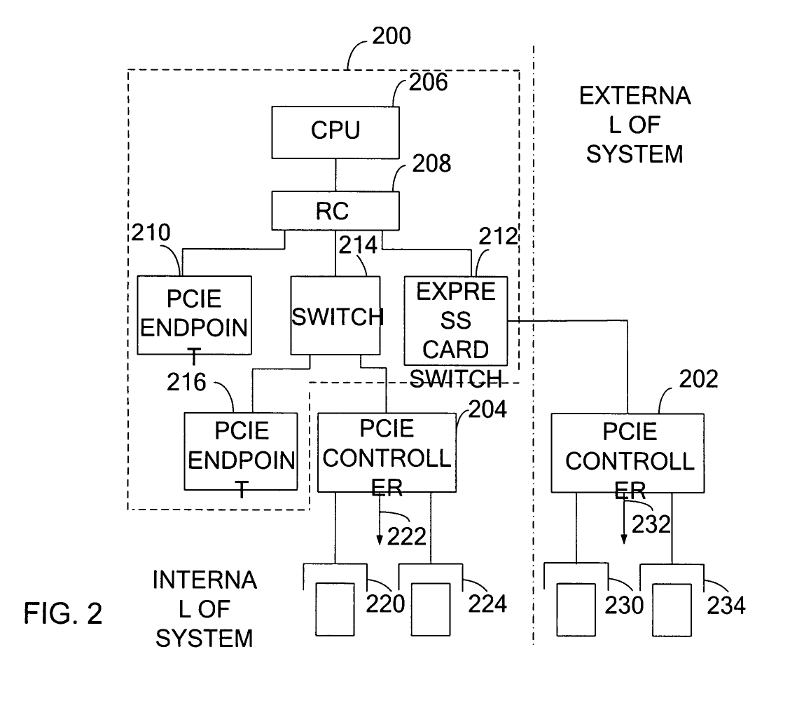

Referring to FIG. 2, a schematic representation of a host system 200 with the controller core shown in FIG. 1 is illustrated, in accordance with one embodiment of the present invention. As mentioned above, the PCI-E controller core 100 shown in FIG. 1 can be formed as an integrated internal PCI-E controller or an external ExpressCard module which is applied to the system 200 as an integrated internal PCI-E controller 204 or an external ExpressCard module 202. It will be apparent to those skilled in the art that the host computer system 200 which can be a PCI-E based computer system comprises a Central Processing Unit (CPU) 206, a Root Complex (RC) 208 coupled to CPU 206, a PCI-E endpoint 210 and a switch 214 coupled to RC 208, and a PCI-E endpoint 216 coupled to the switch 214. It should be understood that the RC 208, the switch 214 and the endpoint 210 are defined in PCI-E specification.

The RC 208 denotes the root of an I/O hierarchy coupled to the CPU 206. The RC 208 may support one or more PCI-E ports or interfaces. Each interface defines a separate I/O hierarchy domain. Each hierarchy domain may be composed of a single I/O Endpoint, such as the PCI-E endpoint 210, or a sub-hierarchy containing one or more switch components and I/O endpoints, such as the switch 214 and the PCI-E endpoint 216.

As defined in the PCI-E specification, the PCI-E endpoints 210 and 216 refer to a type of device that can be the requester or completer of a PCI-E transaction either on its own behalf or on behalf of a distinct non-PCI Express device, such as a PCI-E attached graphics controller (not shown) or a PCI Express-USB interface (not shown).

In one embodiment, the controller core 100 shown in FIG. 1 is packaged to be formed as an Integrated Circuit (IC) chip, such as the PCI-E controller 204 or the PCI-E controller 202. In one embodiment, the PCI-E controller 204 complies with the PCI-E protocol and will be recognized as an internal component. The PCI-E controller 204 is coupled to the switch 214 when the PCI-E controller 204 is integrated or equipped into the system 200. The standard configuration register unit in the controller 204 is enabled by the bond option signal (e.g., 112 in FIG. 1) for supporting the PCI-E communication function.

In another embodiment, the ExpressCard module 202 complies with the PCI-E protocol and will be recognized as an external component. The ExpressCard module 202 is coupled to the host computer system 200 when it inserted into the ExpressCard switch 212. The ExpressCard Switch 212 having a PCI-E interface slot is coupled to the RC 208. The bond option signal (discussed above) enables the capabilities register unit and logic unit as well as the standard configuration unit (also discussed above) to support the hot-plug and hot-swap function of the controller 202.

As defined in PCI-E specifications, the power management states (D-states) includes D0, D1, D2, D3 states. The ExpressCard controller 202 is designed to support these power states for cooperating with the host computer system 200 and providing maximum power savings according to the ExpressCard standard. D0 state is supported by all PCI-E functions, and divided into two sub-states, “un-initialized” sub-state and the “active” sub-state. When a PCI-E component initially has its power applied, it defaults to the D0_{uninitialized} state. D1 and D2 supports are optional. D3 support is required (both D3_{cold} and D3ₕₒₜ) for PCI-E components. When a function is in D3ₕₒₜ, it must respond to configuration accesses targeting it, and it can later be transitioned into D3_{cold} state when its power is removed. A power-on sequence with its associated cold reset transitions a function from the D3_{cold} state to the D0_{uninititialized} state.

When the ExpressCard module 202 is inserted into the host computer system 200, the PCI-E interface detect logic signal, such as signal CPPE#, will inform the host system 200 that a module/controller is present in the slot and will be used by the host computer system 200 to turn on the power in the slot. When the module 202 is inserted into it, the host computer system 200 may be in one of three different conditions: (1) the module 202 may be inserted prior to system power being available; (2) the module 202 may be inserted during normal system operation; or (3) the module 202 is inserted while the system 200 is in a sleep state. Whatever power state the host system 200 is in, the controller 202 will support the operation of the module 202 and the module slot will be powered. The clock request logic signal 116, such as signal CLKREQ# is asserted to the host platform when the module 202 needs to have reference clock. The state of CLKREQ# should essentially track the device state of the PCI-E function for requesting the reference clock when the device is in D0 state and for turning off that request when the device is in D3 state.

In accordance with embodiments of the present invention, by the bond option signal, the adaptable controller core can be enabled to be installed into the host computer system 200 as an internal PCI-E controller 204 or to be plugged into a slot of the host computer system 200 as an external ExpressCard module 202.

In one embodiment of the present invention, the PCI-E controller 204 further comprises an additional register and logic unit 120, shown in FIG. 1, which can be selected by MUX units 108 and 110 for supporting other communication bus interfaces, such as a Media Card interface 220, an Electrical and Electronics Engineers (IEEE) 1394 interface 222, and a CardBus interface 224 shown in FIG. 2. It should be understood by those skilled in the art that the external device communication bus interfaces should not be limited to these three interfaces 220, 222 and 224, and aforesaid three buses can be used in any combinations. For instance, the integrated PCI-E controller 204 can support a Media Card interface 220 when the Media Card slot is integrated into the controller 204. As such, a Media Card can be inserted into the slot and communicated with host system 200 by using PCI-E controller 204. Similarly, the IEEE 1394 interface 222 can be integrated into the system 200 by adding relevant registers and logics to the controller core (e.g., 100 in FIG. 1). The communication protocols of external device communication buses, such as, CardBus, Media Card, IEEE 1394, are defined in the Specifications, respectively.

Similarly, when the controller core (e.g., 100 in FIG. 1) which can further support external device communication bus interfaces is packaged into the external ExpressCard module 202 according to ExpressCard standard, a Media Card interface 230, an IEEE 1394 interface 232, and a CardBus interface 234 can also be integrated for supporting the Media Card, IEEE 1394 and CardBus communications.

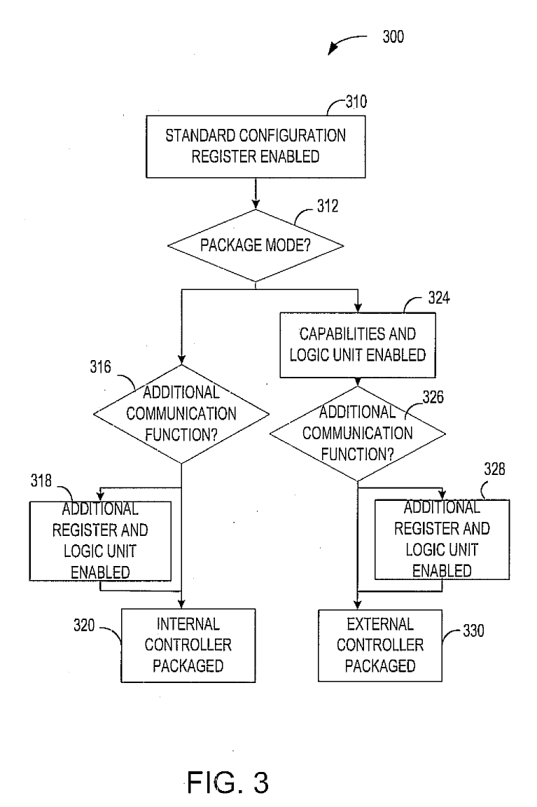

Referring to FIG. 3, steps in a method 300 for manufacturing/producing a PCI-E controller are shown. As shown in FIG. 3, at 310, a standard configuration register unit in a controller core is configured for supporting the controller core when it is embedded internally or externally accessible. After enabling this standard unit, the basic PCI-E function communication defined in PCI-E Specification can be realized. During manufacturing the PCI-E controller, a bond option signal can be used to enable the standard unit.

At 312, the package mode of the controller core is determined. In this step, the controller core is determined to be formed as an internal chip or an external chip. If the controller core is determined to be formed as an internal chip, then step 316 is executed, otherwise step 324 is executed.

At 316, it is determined whether additional communication function of the internal controller core is to be enabled or disenabled, or in other words, it is determined whether the internal controller core is to support other communication bus interfaces. If the controller core die is determined to be formed as an internal chip without supporting the function of communicating with other buses, such as CardBus, IEEE 1394 and Media Card etc., then go to 320, otherwise go to 318.

At 318, an additional register and logic unit of the controller core is enabled by the bond option signal for supporting other external device communication bus interfaces. These interfaces can be, but not limited to be interpreted as: CardBus interface, IEEE 1394 interface, Media Card interface etc, and can be any combination of these communication bus interfaces.

At 320, the controller core is packaged into a chip which can be integrated into a host computer system and can be recognized as an internal device by the Operating System (OS) and the Basic Input/Output System (BIOS) of the host computer system.

At 324, a capabilities register unit and a logic unit of the controller core are enabled for identifying hot insertion and removal. The capabilities register unit and logic unit are used for providing hot-plug and hot-swap capability. The bond option signal (see discussion made with reference to FIG. 1) can also be used to enable the capabilities register unit and the logic unit. A selector can be coupled to the bond option signal for optionally enabling the capabilities register unit and the logic unit.

At 326, it is determined whether additional communication function of the external controller core is to be enabled or disenabled, or in other words, it is determined whether the external controller core is to support other communication bus interfaces. If the controller core die is determined to be formed as an external chip without supporting the function of communicating with other buses, such as CardBus, IEEE 1394 and Media Card etc., then go to 330, otherwise go to 328.

At 328, an additional register and logic unit of the external controller core is enabled by the bond option signal for supporting other external device communication bus interfaces. These interfaces can be, but not limited to be interpreted as: CardBus interface, IEEE 1394 interface, Media Card interface etc, and can be any combination of these communication bus interfaces.

At 330, the controller core is packaged into a chip which will be recognized as an external device of a host computer system by the OS and the BIOS of the host computer system when the chip is plugged into the host computer system.

While the foregoing description and drawings represent the preferred embodiments of the present invention, it will be understood that various additions, modifications and substitutions may be made therein without departing from the spirit and scope of the principles of the present invention as defined in the accompanying claims. One skilled in the art will appreciate that the invention may be used with many modifications of form, structure, arrangement, proportions, materials, elements, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims and their legal equivalents, and not limited to the foregoing description.

What is claimed is:

1. A controller core for controlling communication of Peripheral Component Interconnect (PCI) Express interface, comprising:
a standard configuration register unit configured for controlling the communication of said PCI Express interface, and supporting said controller core being embedded internally and externally accessible;
a capabilities register unit; and
a logic unit associated with said standard configuration register unit and said capabilities register unit for identifying a hot insertion and removal from an exterior of said controller core, wherein a bond option signal is used to enable and disenable said standard configuration register unit, said capabilities register unit, and said logic unit respectively.

2. The controller core as claimed in claim 1, further comprising a selector coupled to said standard configuration register unit and said capabilities register unit for enabling said capabilities register unit and said standard configuration register unit in response to said bond option signal.

3. The controller core as claimed in claim 1, wherein said controller core is a part of a host computer system and is recognized as an internal device of said host computer system when said standard configuration register unit is enabled by said bond option signal.

4. The controller core as claimed in claim 3, wherein said controller core is installed into said host computer system and is recognized as said internal device by an Operating System (OS) and Basic Input/Output System (BIOS) of said host computer system.

5. The controller core as claimed in claim 1, wherein said controller core is a part of an external chip, said capabilities register unit and said logic unit is enabled by said bond option signal, and said controller core is recognized as an external device when plugged into said host computer system.

6. The controller core as claimed in claim 5, wherein said controller core is plugged into said host computer system and is recognized as said external device by an Operating System (OS) and Basic Input/Output System (BIOS) of said host computer system.

7. The controller core as claimed in claim 5, wherein said external device is an ExpressCard module.

8. The controller core as claimed in claim 1, wherein said capabilities registers comprises:
a plurality of slot capabilities registers for identifying said hot insertion and removal from an exterior of said controller core.

9. The controller core as claimed in claim 1, wherein said logic unit comprises:
a PCI Express interface detect logic signal for detecting a PCI Express based device;
a clock request logic signal for providing a reference clock signal to said PCI-E based device.

10. The controller core as claimed in claim 1, further comprising:
an additional register and logic unit which is enabled by said bond option signal for supporting at least one external device communication bus interface.

11. The controller core as claimed in claim 10, wherein said external device communication bus interface is an Institute of Electrical and Electronics Engineers (IEEE) 1394 interface.

12. The controller core as claimed in claim 10, wherein said external device communication bus interface is a Media Card interface.

13. The controller core as claimed in claim 10, wherein said external device communication bus interface is a CardBus interface.

14. A method for producing a controller core controlling a PCI-E communication, said method comprising:
enabling a standard configuration register unit of said controller core by a bond option signal, wherein said standard configuration register unit is configured for supporting said PCI-E communication;
determining whether said controller core is packaged as an internal chip or an external chip;
packaging said controller core into said internal chip if said controller core is determined to be packaged as said internal chip; and
enabling a capabilities register unit and a logic unit of said controller core by said bond option signal and packing said controller core into said external chip, if said controller core is determined to be packaged as said external chip, wherein said capabilities register unit and said logic unit are applied for identifying a hot insertion and removal from exterior of said controller core.

15. The method as claimed in claim 14, further comprising:
enabling an additional register and logic unit of said controller core by said bond option signal for supporting at least one external device communication bus interface.

16. The method as claimed in claim 15, wherein said external device communication bus interface is an Institute of Electrical and Electronics Engineers (IEEE) 1394 interface.

17. The method as claimed in claim 15, wherein said external device communication bus interface is a Media Card interface.

18. The method as claimed in claim 15, wherein said external device communication bus interface is a CardBus interface.

19. The method as claimed in claim 14, wherein said capabilities registers comprises:
a plurality of slot capabilities registers for identifying said hot insertion and removal from exterior of said controller core.

20. The method as claimed in claim 14, wherein said logic unit comprises:
a PCI-E interface detect logic signal for detecting a PCI-E based device;
a clock request logic signal for providing a reference clock signal to said PCI-E based device.
